(19) United States
(12) Patent Application Publication
(10) Pub. No.: US 2008/0124822 A1
(43) Pub. Date: May 29, 2008

(54) Thermosetting resin composition and photo-semiconductor encapsulant

(75) Inventor: Yuji Yoshikawa, Gunma-ken (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: Shin-Etsu Chemical Co., Ltd., Tokyo (JP)

(21) Appl. No.: 12/010,143

(22) Filed: Jan. 22, 2008

Related U.S. Application Data
(62) Division of application No. 11/006,711, filed on Dec. 8, 2004.

(30) Foreign Application Priority Data
Dec. 9, 2003 (JP) 2003-410576

(51) Int. Cl. H01L 33/00; H01L 31/18

(52) U.S. Cl. 438/26; 438/64; 257/E33.059; 257/E31.117

(57) ABSTRACT

A method of encapsulating a photo-semiconductor device using a thermosetting resin composition comprising (A) a silicone compound containing at least two epoxy groups per molecule and having a molecular weight of 500-2, 100, (B) an acid anhydride, and (C) an optional catalyst, which cures into a low-stressed product having improved adhesion, heat resistance and moisture resistance and being free of cure shrinkage.

### CROSS-REFERENCE TO RELATED APPLICATION

This application is a divisional of application Ser. No. 11/006,711, filed on Dec. 8, 2004, which claims priority under 35 U.S.C. §119(a) on Patent Application No. 2003-410576 filed in Japan on Dec. 9, 2003, the entire contents of which are hereby incorporated by reference.

### TECHNICAL FIELD

This invention relates to a thermosetting resin composition and a photo-semiconductor encapsulant. More particularly, it relates to a thermosetting resin composition comprising an epoxy resin, especially a cyclohexyl-containing silicone and an acid anhydride which cures through acid-epoxy reaction into a cured product having transparency, heat resistance and toughness, especially a low-stress cured product having adhesion to semiconductor members and lead frames, heat resistance and moisture resistance, and free of cure shrinkage and being suited for the encapsulation of photo-semiconductor devices.

### BACKGROUND ART

It is well known that epoxy resin compositions using acid anhydride curing agents which cure into transparent products are suited for the encapsulation of photo-semiconductor devices such as light-emitting diodes and photodiodes. In compositions of this type, curing accelerators such as tertiary amines, imidazoles and organic metal complex salts are used in combination with the acid anhydride curing agents to improve the curing rate.

However, conventional epoxy resin compositions have the problem that elevating the curing temperature or increasing the amount of curing accelerator to accelerate cure results in cured products which are yellowed to such an extent to prevent their use as the photo-semiconductor device encapsulant.

Japanese Patent No. 2,534,642 discloses a composition comprising a bisphenol type epoxy resin or cycloaliphatic epoxy resin, an acid anhydride curing agent, and a quaternary ammonium salt, which is fast curing and restrained from discoloration. Japanese Patent No. 2,703,609 proposes the use of multifunctional cycloaliphatic epoxy organic compounds for improving heat resistance, impact resistance and moisture resistance.

As the modern photo-semiconductor devices are improved in performance, the encapsulating resins are also required of better performance. In addition to heat resistance and moisture resistance, weather resistance and low stress are also required. Compositions based on bisphenol A epoxy resins, bisphenol F epoxy resins or epoxy resins of organic resin skeleton such as (3′,4′-epoxycyclohexane)methyl 3,4-epoxycyclohexanecarboxylate fail to provide such better properties.

To provide low stress compositions while maintaining heat resistance, Japanese Patent Nos. 2,760,889 and 2,796,187 propose the addition of amino group-containing silicone and crack-free spherical silica, respectively. These compositions are less adherent to photo-semiconductors and lead frames and prone to separate apart, which causes a loss of moisture resistance. The results are far from the satisfaction.

Therefore, it is desired to have a transparent epoxy resin composition having low stress, heat resistance and good adhesion to photo-semiconductors and lead frames.

### SUMMARY OF THE INVENTION

An object of the invention is to provide a thermosetting resin composition which cures into a low stressed product having improved adhesion, heat resistance and moisture resistance and free of cure shrinkage, and is thus suited for the encapsulation of photo-semiconductors. Another object is to provide a photo-semiconductor encapsulant.

The inventors have found that a thermosetting resin composition featuring low stress as well as adhesion, heat resistance and moisture resistance is arrived at by combining a specific cycloaliphatic epoxy group-modified silicone having a relatively low molecular weight and many epoxy groups as proposed in JP-A 2003-29281, JP-A 2003-29282 and JP-A 2003-29283, with an acid anhydride curing agent and an optional catalyst.

As compared with the prior art compositions based on bisphenol A epoxy resins, bisphenol F epoxy resins or epoxy resins of organic resin skeleton such as (3′,4′-epoxycyclo-hexane)methyl 3,4-epoxycyclohexanecarboxylate, the inventive thermosetting resin composition is fully heat resistant and moisture resistant, free of cure shrinkage and low stressed because the base resin has a siloxane skeleton.

Therefore, the present invention provides a thermosetting resin composition comprising

(A) 100 parts by weight of a silicone compound containing at least two epoxy groups per molecule and having a molecular weight of 500 to 2,100,

(B) 20 to 200 parts by weight of an acid anhydride, and

(C) 0 to 5 parts by weight of a catalyst.

When heated, the inventive resin composition cures without shrinkage into a transparent product which exhibits good adhesion, heat resistance, moisture resistance and low stress.

### DESCRIPTION OF THE PREFERRED EMBODIMENTS

The thermosetting resin composition of the present invention is defined as comprising

(A) a silicone compound containing at least two epoxy groups per molecule and having a molecular weight of 500 to 2,100,

(B) an acid anhydride, and optionally,

(C) a catalyst.

In a preferred embodiment, component (A) comprises (A′) a silicone compound containing at least three epoxycyclohexyl groups per molecule, having an epoxycyclohexyl equivalent of 180 to 230, especially 184 to 216, and typically a molecular weight of 700 to 1,900, and being free of alkoxy groups. This silicone compound is more reactive and permits the amount of component (C) added to be reduced, leading to low color. If alkoxy groups are contained, cure shrinkage can occur through alcohol-removal reaction, resulting in a low strength.

As used herein, the term “epoxycyclohexyl equivalent” of a silicone compound refers to the mass of the compound per mole of epoxycyclohexyl group. For a polymer having a molecular weight distribution, the term “molecular weight” refers to the weight average molecular weight as measured by gel permeation chromatography (GPC) versus styrene standards.

It is noted that when a silicone compound consists solely of silane units constituting cycloaliphatic epoxy groups, the industrial synthesis of a compound having an epoxycyclohexyl equivalent of less than 180 is difficult. An epoxycyclohexyl equivalent of more than 230 corresponds to a less content of cycloaliphatic epoxy groups, which may be insufficient to provide strength. A silicone compound with a molecular weight of less than 500 is prone to cure shrinkage. It is difficult to synthesize industrially a silicone compound having a molecular weight of more than 2,100 and an epoxycyclohexyl equivalent of 180 to 230.

Preferred component (A′) is a silicone compound comprising units —R¹CH₃SiO_{2/2}— wherein R¹ is an organic group containing an epoxycyclohexyl group, containing at least three R¹ groups per molecule, having an epoxycyclohexyl equivalent of 180 to 220, especially 184 to 216, and typically a molecular weight of 500 to 2,100, especially 700 to 1,900, and being free of alkoxy groups. Component (A′) may have any of branched, linear and cyclic structures.

The silicone compounds of linear structure include silicone compounds having the formula:

R³(CH₃)₂SiO(R¹CH₃SiO)ₐ(R²CH₃SiO)_{b}Si(CH₃)₂R³

wherein R¹ is an organic group containing an epoxycyclohexyl group, R² is hydrogen or an organic group other than R¹, R³ is R¹ or R², “a” is an integer of 2 to 10, “b” is an integer of 0 to 8, and the sum of a+b is 2 to 10; and more preferably silicone compounds having the formula:

(CH₃)₃SiO(R¹CH₃SiO)ₘSi(CH₃)₃

wherein R¹ is as defined above, and m is an integer of 2 to 10.

The silicone compounds of cyclic structure include silicone compounds having the formula:

(R¹CH₃SiO)_{c}(R²CH₃SiO)_{d}

wherein R¹ is an organic group containing an epoxycyclohexyl group, R² is hydrogen or an organic group other than R¹, “c” is an integer of 2 to 5, “d” is an integer of 0 to 3, and the sum of c+d is 3 to 5; and more preferably silicone compounds having the formula:

(R¹CH₃SiO)ₙ

wherein R¹ is as defined above and n is an integer of 3 to 5.

Specifically, R¹ is an organic group containing an epoxycyclohexyl group, for example, epoxycyclohexylakyl groups such as 3,4-epoxycyclohexylethyl. R² is hydrogen or an organic group other than R¹, preferably of 1 to 20 carbon atoms, more preferably 1 to 10 carbon atoms. Exemplary organic groups are substituted or unsubstituted monovalent hydrocarbon groups, for example, alkyl groups such as methyl, ethyl, propyl, butyl, hexyl and octyl, aryl groups such as phenyl and tolyl, alkenyl groups such as vinyl and allyl, and substituted forms of the foregoing groups in which some or all of the hydrogen atoms are replaced by halogen atoms (e.g., fluoro), glycidyl, methacrylic, acrylic, mercapto or amino groups.

Linear and cyclic structures free of branching are preferred because of lower stresses.

Illustrative examples of the silicone compounds are given below wherein R¹ is as defined above.

(R¹(CH₃)₂SiO)₃CH₃Si

(R¹(CH₃)₂SiO)₄Si

(CH₃)₃SiO(R¹CH₃SiO)₄Si (CH₃)₃

(CH₃)₃SiO(R¹CH₃SiO)₅Si(CH₃)₃

(CH₃)₃SiO(R¹CH₃SiO)₆Si (CH₃)₃

(CH₃)₃SiO(R¹CH₃SiO)₇Si(CH₃)³

(CH₃)₃SiO(R¹CH₃SiO)₈Si(CH₃)₃

(CH₃)₃SiO(R¹CH₃SiO)₉Si(CH₃)₃

(CH₃)₃SiO(R¹CH₃SiO)₁₀Si(CH₃)₃

R¹(CH₃)₂SiO(R¹CH₃SiO)Si(CH₃)₂R¹

R¹(CH₃)₂SiO(R¹CH₃SiO)₂Si(CH₃)₂R¹

R¹(CH₃)₂SiO(R¹CH₃SiO)₃Si(CH₃)₂R¹

R¹(CH₃)₂SiO(R¹CH₃SiO)₄Si (CH₃)₂R¹

R¹(CH₃)₂SiO(R¹CH₃SiO)₅Si(CH₃)₂R¹

R¹(CH₃)₂SiO(R¹CH₃SiO)₆Si(CH₃)₂R¹

R¹ (CH₃)₂SiO(R¹CH₃SiO)₇Si(CH₃)₂R¹

R¹(CH₃)₂SiO(R¹CH₃SiO)₈Si(CH₃)₂R¹

R¹(CH₃)₂SiO(R¹CH₃SiO)₉Si(CH₃)₂)R¹

R¹(CH₃)₂SiO(R¹CH₃SiO)₂((CH₃)₂SiO)₂Si(CH₃)₂R¹

R¹(CH₃)₂SiO(R¹CH₃SiO)₃((CH₃)₂SiO)Si(CH₃)₂R¹

R¹(CH₃)₂SiO(R¹CH₃SiO)₃((CH₃)₂SiO)₂Si(CH₃)₂R¹

R¹(CH₃)₂SiO(R¹CH₃SiO)₄((CH₃)₂SiO)Si(CH₃)₂R¹

R¹(CH₃)₂SiO(R¹CH₃SiO)₄((CH₃)₂SiO)₂Si(CH₃)₂R¹

R¹(CH₃)₂SiO(R¹CH₃SiO)₅((CH₃)₂SiO)Si(CH₃)₂R¹

R¹(CH₃)₂SiO(R¹CH₃SiO)₅((CH₃)₂SiO)₂Si(CH₃)₂R¹

R¹(CH₃)₂SiO(R¹CH₃SiO)₅((CH₃)₂SiO)₃Si(CH₃)₂R¹

R¹(CH₃)₂SiO(R¹CH₃SiO)₆((CH₃)₂SiO)Si(CH₃)₂R¹

R¹(CH₃)₂SiO(R¹CH₃SiO)₆((CH₃)₂SiO)₂Si(CH₃)₂R¹

R¹(CH₃)₂SiO(R¹CH₃SiO)₆((CH₃)₂SiO)₂Si(CH₃)₂R¹

R¹(CH₃)₂SiO(R¹CH₃SiO)₇((CH₃)₂SiO)Si(CH₃)₂R¹

R¹(CH₃)₂SiO(R¹CH₃SiO)₇((CH₃)₂SiO)₂Si(CH₃)₂R¹

R¹(CH₃)₂SiO(R¹CH₃SiO)₇((CH₃)₂SiO)₃Si(CH₃)₂R¹

R¹(CH₃)₂SiO(R¹CH₃SiO)₇((CH₃)₂SiO)₄Si (CH₃)₂R¹

R¹(CH₃)₂SiO(R¹CH₃SiO)₈((CH₃)₂SiO)Si(CH₃)₂R¹

R¹(CH₃)₂SiO(R¹CH₃SiO)₈((CH₃)₂Sio)₂Si(CH₃)₂R¹

R¹(CH₃)₂SiO(R¹CH₃SiO)₈((CH₃)₂Sio)₃Si(CH₃)₂R¹

(R¹CH₃SiO)₃

(R¹CH₃SiO)₄

(R¹CH₃SiO)₅

(R¹CH₃SiO)₃ ((CH₃)₂SiO)

(R¹CH₃SiO)₃(C₃H₇(CH₃)SiO)

These compounds used as component (A) can be prepared by such techniques as hydrolysis of an epoxy group-bearing alkoxysilane alone or in admixture with another alkoxysilane, or addition reaction (or hydrosilylation) of allyl glycidyl ether or 4-vinylcyclohexene epoxide to hydrogenpolysiloxane in the presence of a platinum compound or similar catalyst.

In the practice of the invention, (A″) a silicone compound containing two epoxycyclohexyl groups per molecule, having a molecular weight of 380 to 1,000 and an epoxycyclohexyl equivalent of 190 to 500, and being free of alkoxy groups, may be compounded as part of component (A). The use of one or more species of component (A′) in combination with one or more species of component (A″) enables further stress reduction.

Illustrative examples of the silicone compounds (A″) are given below wherein R¹ is as defined above.

R¹ (CH₃)₂SiOSi(CH₃)₂R¹

R¹(CH₃)₂SiO(CH₃)₂SiOSi(CH₃)₂R¹

R¹(CH₃)₂SiO((CH₃)₂SiO)₂Si(CH₃)₂R¹

R¹(CH₃)₂SiO((CH₃)₂SiO)₃Si(CH₃)₂R¹

R¹ (CH₃)₂SiO((CH₃)₂Sio)₄Si(CH₃)₂R¹

R¹ (CH₃)₂SiO((CH₃)₂SiO)₅Si(CH₃)₂R¹

R¹(CH₃)₂SiO((CH₃)₂SiO)₆Si(CH₃)₂R¹

R¹(CH₃)₂SiO((CH₃)₂SiO)₇Si(CH₃)₂R¹

R¹(CH₃)₂SiO((CH₃)₂SiO)₈Si(CH₃)₂R¹

(R¹CH₃SiO)₂ ((CH₃)₂SiO)₂

(R¹CH₃SiO)₂ (C₃H₇ (CH₃) SiO)₂

The silicone compound (A″) is compounded in an amount of 0 to 30% by weight based on component (A). The amount of the silicone compound (A″), when used, is preferably at least 1% by weight for the compound to exert its effect to a substantial extent. More than 30% by weight of compound (A″) interferes with hardness, resulting in a soft composition.

Component (B) is an acid anhydride which is dissolvable in component (A). Any acid anhydride can be used as long as it reacts with component (A).

Examples of component (B) include colorless or pale yellow acid anhydrides such as hexahydrophthalic anhydride, tetrahydrophthalic anhydride, hexahydromethylphthalic anhydride, tetrahydromethylphthalic anhydride, phthalic anhydride, trimellitic anhydride, pyromellitic anhydride, and succinic anhydride, alone or in admixture of two or more. The preferred acid anhydride is hexahydro-4-methylphthalic anhydride.

The acid anhydride is preferably compounded in an amount corresponding to 0.2 to 5 equivalents, especially 0.5 to 2 equivalents relative to the epoxy groups in component (A). Generally, the acid anhydride is compounded in an amount of 20 to 200 parts by weight, preferably 30 to 150 parts by weight, more preferably 50 to 120 parts by weight, per 100 parts by weight of component (A). Too less amounts of the acid anhydride allow yellowing and exacerbate moisture resistance after curing whereas too much amounts exacerbate moisture resistance. In either case, the composition used as an LED encapsulant can cause chip corrosion and wire breakage, leading to a reduced device lifetime.

Component (C) is a catalyst for promoting reaction of components (A) and (B). Catalysts include imidazole compounds, amine compounds, organometallic complex salts, organophosphine compounds, and quaternary ammonium salts.

Illustrative examples include 2-methylimidazole, 2-ethyl-4-methylimidazole, 1,8-diazabicyclo[5.4.0]undec-7-ene, amine compounds and salts thereof, such as trimethylamine, triethylamine, dimethylbenzylamine and 2,4,6-trisdimethylaminomethylphenol, aluminum chelates, and organophosphine compounds such as tetra-n-butylphosphonium benzotriazolate and tetra-n-butylphosphonium-0,0-diethylphosphorodithioate.

Generally, the catalyst is compounded in an amount of 0 to 5 parts by weight, preferably 0.01 to 5 parts by weight, more preferably 0.01 to 1 part by weight, per 100 parts by weight of component (A). Less than 0.01 pbw of the catalyst will be ineffective for cure promotion whereas more than 5 pbw allows yellowing and exacerbates moisture resistance after curing.

In the practice of the invention, (D) an organic resin is preferably compounded in the composition for imparting adhesion, flexibility or other properties. Useful organic resins include epoxy resins, acrylic resins, polyester resins, and polyimide resins. Those resins having groups capable of reacting with the other components are preferred, with epoxy resins being more preferred.

Useful epoxy resins are those resins exemplified above for component (A), but free of silicon atoms. Examples include bisphenol A epoxy resins, bisphenol F epoxy resins, hydrogenated epoxy resins, and 3,4-epoxycyclohexylmethyl 3,4-epoxycyclohexanecarboxylate.

Generally, the organic resin is compounded in an amount of 0 to 80 parts by weight, preferably 0 to 30 parts by weight, per 100 parts by weight of component (A). More than 80 pbw of the organic resin may allow yellowing and exacerbate moisture resistance after curing. The amount of the organic resin, when compounded, should preferably be at least 5 pbw, more preferably at least 10 pbw, per 100 pbw of component (A) for the resin to exert its effect to a significant extent.

If desired, various additives such as dyes, anti-degradants, parting agents, and diluents are compounded in the thermosetting resin composition of the invention.

The thermosetting resin composition comprising the above-described components is normally liquid, and cures by heating at 100 to 200° C. A heating temperature in excess of 200° C. is undesirable because of yellowing. When used for the encapsulation of photo-semiconductor members, the resin composition cures into a transparent product which undergoes little or no discoloration at a curing temperature of 180° C. or lower. Even in a relatively low temperature region of 80 to 150° C., the composition cures within a short time of about 30 to 60 minutes if the amount of component (C) added is increased. Parting of the cured product from the mold is possible. The cured product is transparent and not discolored. Even when the cured composition is post-cured at a temperature of 180° C. or lower, it undergoes no discoloration and remains fully transparent.

The thermosetting resin composition is suited for the encapsulation of photo-semiconductor members including LED lamps, LED chips, semiconductor lasers, photocouplers, and photodiodes.

### EXAMPLE

Examples of the invention are given below by way of illustration and not by way of limitation. All parts are by weight.

In each Example, a solution as compounded was cast into a mold of 100 mm×10 mm×4 mm, and cured in two stages of 100° C. for 2 hours and 170° C. for 2 hours, obtaining a molded part. The molded part was measured for hardness (Shore D), a change of specific gravity before and after curing (abbreviated as SG ratio), flexural modulus (JIS K-5401), transparency (as visually observed) and adhesion to different substrates (crosshatch adhesion test). It is noted that the change of specific gravity (SG) before and after curing is calculated according to [(SG before curing)−(SG after curing)]/(SG after curing), the SG being measured at 25° C.

In the formulae, R^{e} is 3,4-epoxycyclohexylethyl.

### Example 1

A liquid mixture was prepared by mixing 106 parts of (CH₃)₃SiO(R^{e}CH₃SiO)₆Si(CH₃)₃ having a molecular weight of 1,266 and an epoxycyclohexyl equivalent of 211 as component (A), 84 parts of hexahydrophthalic anhydride, 0.4 parts of dimethylbenzylamine, and 2.4 parts of ethylene glycol. The liquid mixture was cast into a mold and cured at 100° C. for 2 hours and at 170° C. for 2 hours, obtaining a molded part.

### Example 2

The procedure of Example 1 was repeated except that 102 parts of (CH₃)₃SiO(R^{e}CH₃SiO)₈Si(CH₃)₃ having a molecular weight of 1,634 and an epoxycyclohexyl equivalent of 204 was used as component (A).

### Example 3

The procedure of Example 1 was repeated except that 92 parts of (R^{e}CH₃SiO)₄ having a molecular weight of 736 and an epoxycyclohexyl equivalent of 184 was used as component (A).

### Example 4

The procedure of Example 1 was repeated except that 113 parts of (CH₃)₃SiO(R^{e}CH₃SiO)₄Si(CH₃)₃ having a molecular weight of 898 and an epoxycyclohexyl equivalent of 225 was used as component (A).

### Example 5

The procedure of Example 1 was repeated except that 107 parts of (R^{e}(CH₃)₂Sio)₃CH₃Si having a molecular weight of 640 and an epoxycyclohexyl equivalent of 213 was used as component (A).

### Example 6

The procedure of Example 1 was repeated except that 103 parts of (R¹(CH₃)₂SiO)₄Si having a molecular weight of 824 and an epoxycyclohexyl equivalent of 206 was used as component (A).

### Example 7

The procedure of Example 1 was repeated except that 113 parts of a hydrolytic condensate of 60 mol % β-(3′,4′-epoxycyclohexyl)ethyltrimethoxysilane and 40 mol % dimethyldimethoxysilane, having a weight average molecular weight of 2,037 was used as component (A).

### Example 8

The procedure of Example 1 was repeated except that 74 parts of (R^{e}CH₃SiO)₄ and 23 parts of R^{e}(CH₃)₂SiOSi(CH₃)₂R^{e} having a molecular weight of 382 and an epoxycyclohexyl equivalent of 191 were used as component (A).

### Example 9

The procedure of Example 1 was repeated except that 0.4 part of 2-ethyl-4-methylimidazole was used instead of dimethylbenzylamine.

### Example 10

The procedure of Example 1 was repeated except that 0.4 part of aluminum di-n-butoxidemonomethylacetoacetate was used instead of dimethylbenzylamine.

### Example 11

The procedure of Example 1 was repeated except that 5 parts of Epikote 828 (Japan Epoxy Resin Co., Ltd.) was further added.

The results are shown in Table 1.

TABLE 1

| | | Example | | | | | | | | | | |
|---|---|---|---|---|---|---|---|---|---|---|---|---|
| | | 1 | 2 | 3 | 4 | 5 | 6 | 7 | 8 | 9 | 10 | 11 |
| Hardness (Shore D) | | 77 | 78 | 75 | 73 | 73 | 75 | 73 | 72 | 75 | 73 | 70 |
| SG ratio | | 1.5 | 2.0 | 2.2 | −0.5 | 0.8 | 1.1 | −2.1 | −0.1 | 1.7 | 1.4 | −0.3 |
| Flexural modulus | | 2,240 | 2,180 | 2,300 | 2,320 | 2,200 | 2,150 | 2,360 | 2,540 | 2,220 | 2,240 | 2,480 |
| (MPa) | | | | | | | | | | | | |
| Transparency | | ◯ | ◯ | ◯ | ◯ | ◯ | ◯ | ◯ | ◯ | ◯ | ◯ | ◯ |
| Adhesion | Aluminum | ◯ | ◯ | ◯ | ◯ | ◯ | ◯ | ◯ | ◯ | ◯ | ◯ | ◯ |
| | Polycarbonate | ◯ | ◯ | ◯ | ◯ | ◯ | ◯ | ◯ | ◯ | ◯ | ◯ | ◯ |
| | resin | | | | | | | | | | | |
| | Acrylic resin | ◯ | ◯ | ◯ | ◯ | ◯ | ◯ | ◯ | ◯ | ◯ | ◯ | ◯ |
| | Polyphthalamide | ◯ | ◯ | ◯ | ◯ | ◯ | ◯ | ◯ | ◯ | ◯ | ◯ | ◯ |
| | resin | | | | | | | | | | | |

### Comparative Example 1

The procedure of Example 1 was repeated except that 68 parts of (3′,4′-epoxycyclohexyl)methyl 3,4-epoxycyclohexyl-carboxylate was used instead of component (A).

### Comparative Example 2

The procedure of Example 1 was repeated except that 246 parts of β-(3′,4′-epoxycyclohexyl)ethyltrimethoxysilane was used instead of component (A).

### Comparative Example 3

The procedure of Example 1 was repeated except that 89 parts of a hydrolytic condensate of β-(3′,4′-epoxycyclo-hexyl)ethyltrimethoxysilane, having a weight average molecular weight of 2,700 was used instead of component (A).

### Comparative Example 4

The procedure of Example 1 was repeated except that 96 parts of R^{e}(CH₃)₂SiOSi (CH₃)₂R^{e} having a molecular weight of 382 was used instead of component (A).

### Comparative Example 5

The procedure of Example 1 was repeated except that the amount of (CH₃)₃SiO(R^{e}CH₃SiO)₆Si (CH₃)₃ as component (A) was increased from 106 parts to 450 parts.

### Comparative Example 6

The procedure of Example 1 was repeated except that the amount of (CH₃)₃SiO(R^{e}CH₃SiO)₆Si(CH₃)₃ as component (A) was decreased from 106 parts to 18 parts.

The results are shown in Table 2.

TABLE 2

| | | Comparative Example | | | | | |
|---|---|---|---|---|---|---|---|
| | | 1 | 2 | 3 | 4 | 5 | 6 |
| Hardness (Shore D) | | 73 | uncured | 68 | 67 | 73 | 72 |
| SG ratio | | −6.1 | — | −9.8 | −1.2 | −2.5 | −7.9 |
| Flexural modulus (MPa) | | 2,800 | — | 1,300 | 1,620 | 1,660 | 1,550 |
| Transparency | | ∘ | — | ∘ | Δ | x | x |
| Adhesion | Aluminum | ∘ | — | ∘ | ∘ | x | ∘ |
| | Polycarbonate resin | ∘ | — | ∘ | ∘ | x | ∘ |
| | Acrylic resin | ∘ | — | ∘ | ∘ | x | ∘ |
| | Polyphthalamide resin | ∘ | — | ∘ | ∘ | x | ∘ |

The molded parts of Example 1 and Comparative Example 1 were determined for heat loss by heating at a rate of 5° C./min to a predetermined temperature (shown in Table 3). The heat loss is calculated according to [(weight before heating)−(weight after heating)]/(weight before heating)×100%.

TABLE 3
Heat loss (%)

| | Example 1 | Comparative Example 1 |
|---|---|---|
| 200° C. | 0 | 0 |
| 300° C. | 4 | 10 |
| 400° C. | 24 | 100 |
| 500° C. | 65 | 100 |

As seen from the foregoing results, a composition containing a non-silicone compound as in Comparative Example 1 underwent substantial cure shrinkage. An increased heat loss indicates low heat resistance.

A composition containing a monofunctional silane coupling agent as in Comparative Example 2 did not cure.

A composition containing a higher molecular weight compound as in Comparative Example 3 exhibited a lower hardness, cure shrinkage and a low flexural modulus.

A composition containing a difunctional compound alone as in Comparative Example 4 was less transparent.

A composition containing a more or less amount of component (A) as in Comparative Example 5 or 6 exhibited a low flexural modulus and substantial color.

Japanese Patent Application No. 2003-410576 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

We claim:

1. A method comprising the steps of:
providing a thermosetting resin composition comprising
(A) 100 parts by weight of a silicone compound containing at least two epoxy groups per molecule and having a molecular weight of 500 to 2,100,
(B) 20 to 200 parts by weight of an acid anhydride, and
(C) 0.01 to 5 parts by weight of a catalyst selected from the group consisting of dimethylbenzylamine, 2,4,6-trisdimethylaminomethylphenol, aluminum chelates, organophosphine compounds, and mixtures thereof;
encapsulating a photo-semiconductor member selected from the group consisting of LED lamps, LED chips, semiconductor laser, photocouplers and photodiodes; and
curing said thermosetting resin composition.

2. The method of claim 1, wherein component (A) comprises (A′) a silicone compound containing at least three epoxycyclohexyl groups per molecule, having an epoxycyclohexyl equivalent of 180 to 230, and being free of alkoxy groups.

3. The method of claim 2, wherein component (A′) is a silicone compound comprising units —R¹CH₃SiO_{2/2}—
wherein R¹ is an organic group containing an epoxycyclohexyl group, containing at least three R² groups per molecule, having an epoxycyclohexyl equivalent of 180 to 220, and being free of alkoxy groups.

4. The method of claim 3, wherein component (A′) is a silicone compound having the formula:
R³(CH₃)₂SiO(R¹CH₃SiO)ₐ(R²CH₃SiO)_{b}Si(CH₃)₂R³
wherein
R¹ is an organic group containing an epoxycyclohexyl group,
R² is hydrogen or an organic group other than R¹,
R³ is R² or R²,
a is an integer of 2 to 10,
b is an integer of 0 to 8, and
the sum of a+b is 2 to 10.

5. The method of claim 4, wherein component (A′) is a silicone compound having the formula:
(CH₃)₃SiO(R¹CH₃SiO)ₘSi(CH₃)₃
wherein m is an integer of 2 to 10.

6. The method of claim 3, wherein component (A′) is a silicone compound having the formula:
(R¹CH₃SiO)_{c}(R²CH₃SiO)_{d}
wherein
R¹ is an organic group containing an epoxycyclohexyl group,
R² is hydrogen or an organic group other than R¹,
c is an integer of 2 to 5,
d is an integer of 0 to 3, and
the sum of c+d is 3 to 5.

7. The method of claim 6, wherein component (A′) is a silicone compound having the formula:
(R¹CH₃SiO)ₙ
wherein n is an integer of 3 to 5.

8. The method of claim 1, further comprising (D) up to 80 parts by weight of an organic resin.

9. A method of encapsulating a photo-semiconductor device comprising encapsulating a photo-semiconductor member selected from the group consisting of LED lamps, LED chips, semiconductor lasers, photocouplers and photodiodes with a transparent cured product of a thermosetting resin composition comprising
(A′) a silicone compound containing at least three epoxycyclohexyl groups per molecule, having an epoxycyclohexyl equivalent of 180 to 230 and a molecular weight of 700 to 1,900, and being free of alkoxy groups,
(A″) a silicon compound containing two epoxycyclohexyl groups per molecule, having a molecular weight of 380 to 1,000 and an epoxycyclohexyl equivalent of 190 to 500, and being free of alkoxy groups, and
(B) an acid anhydride,
said component (A″) being present in an amount of 1 to 30% by weight based on the total amount of components (A′) and (A″), and
said component (B) being present in an amount of 20 to 200 parts by weight of the total amount of components (A′) and (A″).

10. The method of claim 9, wherein component (A′) is a silicone compound comprising units —R¹CH₃SiO_{2/2}—
wherein R¹ is an organic group containing an epoxycyclohexyl group, containing at least three R¹ groups per molecule, having an epoxycyclohexyl equivalent of 180 to 220, and being free of alkoxy groups.

11. The method of claim 10, wherein component (A′) is a silicone compound having the formula:
R³(CH₃)₂SiO(R¹CH₃SiO)ₐ(R²CH₃SiO)_{b}Si(CH₃)₂R³
wherein
R¹ is an organic group containing an epoxycyclohexyl group,
R² is hydrogen or an organic group other than R¹,
R³ is R¹ or R²,
a is an integer of 2 to 10,
b is an integer of 0 to 8, and
the sum of a+b is 2 to 10.

12. The method of claim 11, wherein component (A′) is a silicone compound having the formula:
(CH₃)₃SiO(R¹CH₃SiO)ₘSi(CH₃)₃
wherein m is an integer of 2 to 10.

13. The method of claim 10, wherein component (A′) is a silicone compound having the formula:
(R¹CH₃SiO)_{c}(R²CH₃SiO)_{d}
wherein R¹ is an organic group containing an epoxycyclohexyl group, R² is hydrogen or an organic group other than R¹, c is an integer of 2 to 5, d is an integer of 0 to 3, and the sum of c+d is 3 to 5.

14. The method of claim 13, wherein component (A′) is a silicone compound having the formula:
(R¹CH₃SiO)ₙ
wherein n is an integer of 3 to 5.

15. The method of claim 9, further comprising (C) a catalyst selected from the group consisting of imidazole compounds, amine compounds, aluminum chelate compounds, organophosphine compounds, and mixtures thereof in an amount of 0.01 to 5 parts by weight per 100 parts by weight of the total amount of component (A′) and (A″).

16. The method of claim 9, further comprising (D) up to 80 parts by weight of an organic resin.

17. A method of encapsulating a photo-semiconductor device comprising the step of encapsulating a photo-semiconductor member selected from the group consisting of LED lamps, LED chips, semiconductor lasers, photocouplers and photodiodes with a transparent cured product of a thermosetting resin composition comprising
(A) 100 parts by weight of a silicone compound containing at least two epoxy groups per molecule and having a molecular weight of 500 to 2,100,
(B) 20 to 200 parts by weight of an acid anhydride,
(C) 0.01 to 5 parts by weight of a catalyst selected from the group consisting of imidazole compounds, amine compounds, aluminum chelate compounds, organophosphine compounds, and mixtures thereof, and
(D) 5 to 80 parts by weight of an organic resin selected from the group consisting of acrylic resins, polyester resins, and polyimide resins.

18. The method of claim 17, wherein component (A) comprises (A′) a silicone compound containing at least three epoxycyclohexyl groups per molecule, having an epoxycyclohexyl equivalent of 180 to 230, and being free of alkoxy groups.

19. The method of claim 18, wherein component (A′) is a silicone compound containing units —R¹CH₃SiO_{2/2}—
wherein R¹ is an organic group containing an epoxycyclohexyl group, containing at least three R¹ groups per molecule, having an epoxycyclohexyl equivalent of 180 to 220, and being free of alkoxy groups.

20. The method of claim 19, wherein component (A′) is a silicone compound having the formula:
R³(CH₃)₂SiO(R¹CH₃SiO)ₐ(R²CH₃SiO)_{b}Si(CH₃)₂R³
wherein R² is an organic group containing an epoxycyclohexyl group, R² is hydrogen or an organic group other than R¹, R³ is R¹ or R², a is an integer of 2 to 10, b is an integer of 0 to 8, and the sum of a+b is 2 to 10.

21. The method of claim 20, wherein component (A′) is a silicone compound having the formula:
(CH₃)₃SiO(R¹CH₃SiO)ₘSi(CH₃)₃
wherein m is an integer of 2 to 10.

22. The method of claim 18, wherein component (A′) is a silicone compound having the formula: (R¹CH₃SiO) (R²CH₃SiO)_{d} wherein
R¹ is an organic group containing an epoxycyclohexyl group,
R² is hydrogen or an organic group other than R¹,
c is an integer of 2 to 5,
d is an integer of 0 to 3, and
the sum of c+d is 3 to 5.

23. The method of claim 22, wherein component (A′) is a silicone compound having the formula:
(R¹CH₃SiO),
wherein n is an integer of 3 to 5.
